(19) United States
(12) Patent Application Publication
(10) Pub. No.: US 2010/0187172 A1
(43) Pub. Date: Jul. 29, 2010

(54) HIGHLY-ORDERED TITANIA NANOTUBE ARRAYS

(75) Inventors: MAGGIE PAULOSE, State College, PA (US); KARTHIK SHANKAR, Edmonton (CA); HARIPRIYA E. PRAKASAM, San Jose, CA (US); SORACHON YORIYA, State College, PA (US); OOMMAN K. VARGHESE, State College, PA (US); CRAIG A. GRIMES, Boalsburg, PA (US)

Correspondence Address: MCKEE, VOORHEES & SEASE, P.L.C.;ATTN: PENNSYLVANIA STATE UNIVERSITY, 801 GRAND AVENUE, SUITE 3200, DES MOINES, IA, 50309-2721, US

(73) Assignee: THE PENN STATE RESEARCH FOUNDATION, University Park, PA (US)

(21) Appl. No.: 12/693,123

(22) Filed: Jan. 25, 2010

Related U.S. Application Data
(63) Continuation of application No. PCT/US2008/071166, filed on Jul. 25, 2008.
(60) Provisional application No. 60/952,116, filed on Jul. 26, 2007.

(30) Foreign Application Priority Data
Jul. 26, 2007 (US) PCT/US2008/071166

(51) Int. Cl. C25D 11/34; H01L 31/0216; B32B 15/04; B01D 39/14

(52) U.S. Cl. 210/506; 205/322; 136/256; 205/50

(57) ABSTRACT

Fabrication of self-aligned closed packed titania nanotube arrays in excess of 10 μm in length and aspect ratio ≈10,000 by potentiostatic anodization of titanium is disclosed. Conditions for achieving complete anodization and absolute tailorability of Ti foil samples resulting in a self-standing mechanically robust titania membrane in excess of 1000 μm are also disclosed.

### CROSS-REFERENCE TO RELATED APPLICATIONS

This application is a U.S. Continuation Application filed under 35 U.S.C. §111(a) and claiming the benefit under 35 U.S.C. §120 of PCT/US2008/071166, filed Jul. 25, 2008, which claims priority to Ser. No. 60/952,116, filed Jul. 26, 2007, the foregoing applications are herein incorporated by reference.

### GRANT REFERENCE

This invention was developed with government support under Grant No. DE-FG02-06ER15772, awarded by The Department of Energy, and under Grant No. CTS-0518269 awarded by the National Science Foundation. The government has certain rights in this invention.

### FIELD OF THE INVENTION

The present invention concerns fabrication of highly-ordered TiO₂ nanotube-arrays of great length and more particularly concerns vertically oriented titanium oxide nanotube arrays exhibiting array lengths from 10 μm and in excess of 1000 μm.

### BACKGROUND OF THE INVENTION

Vertically oriented, highly ordered TiO₂ nanotube arrays made by anodization of Ti thin or thick films are of increasing importance due to their impressive properties in variety of applications including dye sensitized solar cells [1-4], hydrogen generation by water photoelectrolysis [5-9], photocatalysis [10-13], gas sensors [14-19] and biological species [26]. Since the aforementioned applications are closely related to geometric surface area, keen attention needs to be devoted to synthesizing ultra-long TiO₂ nanotube arrays.

### BRIEF SUMMARY OF THE INVENTION

The two basic criteria for growth of the nanotube array are sustained oxidation of the metal, and pore growth by chemical/field assisted dissolution of the formed oxide [15, 16, 22] with nanotube length determined by the dynamic equilibrium between growth and dissolution processes. As a result and in part of this finding, a double-sided anodization of titanium foil samples in a variety of electrolytes resulted in long nanotube arrays separated by a thin barrier layer [20, 21]. Having pioneered and achieved nanotube array synthesis of via anodization in variety of electrolytes, it now comes as a further object, feature, or advantage of the present invention to provide the synthesis of self-aligned hexagonally packed nanotube array lengths from 10 μm in excess of 1000 μm length by anodization of Ti foil.

A further object, feature, or advantage of the present invention to provide a non-aqueous system containing polar organic electrolytes as an electrolytic medium with sufficient concentration of ions for oxidation and pore growth wherein the thickness of the porous oxide is a function of the thickness of the titanium foil.

Yet another object, feature, or advantage of the present invention is to provide the synthesis of self-aligned, highly ordered nanotube arrays from 10 microns and longer from the anodization of metals such as titanium, nickel, hafnium, tantalum, and any other suitable valve metals, materials or alloys thereof.

A still further object, feature, or advantage of the present invention is to provide absolute tailorability of the process in obtaining nanotubes of desired/required lengths.

A further object, feature, or advantage of the present invention is to provide the synthesis of nanotubular arrays in the form of self-standing membranes.

Another object, feature, or advantage of the present invention is to provide a cathode made from a metals such as platinum, nickel, palladium, copper, iron, tungsten, cobalt, chromium, tin, or any other suitable metals, materials or alloys thereof.

Yet another object, feature or advantage of the present invention is to provide a nanotube array anodized at a variety of temperatures to achieve nanotubes with varying geometries.

A further object, feature, or advantage of the present invention is to provide fabrication and application of flat and/or cylindrical, large-area TiO₂ nanotube array membranes of uniform pore size for use as a solar collector or solar cell.

A still further object, feature, or advantage of the present invention is to provide an improved DSSC film which provides an efficient electron path, has a high surface area, and can be grown to lengths which result in photo conversion efficiencies exceeding that of silicon based solar cells.

Another object, feature, or advantage of the present invention is to provide a fabrication and application of flat, as well as cylindrical, large-area TiO₂ nanotube array membranes of uniform pore size suitable for filtering biological species.

A still further object, feature, or advantage of the present invention is to provide control over the various anodization parameters to vary the tube-to-tube connectivity and hence packing density of the nanotubes within the array.

Yet another object, feature, or advantage of the present invention is to provide techniques to precisely control the structural characteristics of the nanotube array films, including individual nanotube dimensions such as pore size, wall thickness, length, tube-to-tube connectivity, and crystallinity.

Another object, feature, or advantage of the present invention is to provide a process wherein ultrasonic agitation and other suitable techniques separate the membrane from any remaining metal substrate.

One or more of the foregoing objects, features or advantages may be achieved by a method of forming a vertically oriented titania nanotube array using electrochemical oxidation. The method includes providing a two-electrode configuration having a working electrode and a counter electrode and anodizing the working electrode in an electrolyte optimized to maintain dynamic equilibrium between growth and dissolution processes to promote growth of the nanotube array by providing sustained chemical oxidation of the working electrode and pore growth by dissolution of formed oxides. In a preferred form, the working electrode is a titanium foil, the counter electrode is platinum, the electrolyte is an ethylene glycol containing NH₄F and H₂O, and the formed oxide is titanium oxide.

One or more of the foregoing objects, features and/or advantages may additionally be achieved by a method for forming a nanotube array using electro-chemical oxidation. The method includes providing a two-electrode configuration having a titanium foil as a working electrode and a platinum foil as a counter electrode, anodizing the titanium foil in an electrolyte solution comprising a wt % of NH₄F and H₂O in a solution of ethylene glycol to form a titanium dioxide, dissolving the titanium dioxide to form the nanotube array of long range order exhibiting close-packing and high aspect ratios, growing the nanotube array to an optimal length given the working electrode thickness by sustained oxidation of the titanium foil and pore growth, and maintaining dynamic equilibrium between growth and dissolution processes by controlling anodization voltage, anodization time and wt % of NH₄F and H₂O in the solution of ethylene glycol.

One or more of the foregoing objects, features and/or advantages may additionally be achieved by a nanotube array. The nanotube array includes a plurality of self-aligned vertically oriented titania nanotubes having lengths of at least 10 μm. The plurality of self-aligned vertically oriented titania nanotube being formed by electrochemical oxidation.

The foregoing objects, features and/or other advantages of the present invention will become apparent from the specification and claims that follow. In the description, reference is made to the accompanying drawings, which form a part hereof, and in which there is shown by illustration and not of limitation a specific form in which the invention may be embodied. Such embodiment does not represent the full scope of the invention, but rather the invention may be employed in a variety of other embodiments and reference is made to the claims herein for interpreting the breadth of the invention.

### BRIEF DESCRIPTION OF THE DRAWINGS

FIG. 1 shows the ratio of wt % NH₄F to vol % H2O in obtaining maximum growth rate for a given concentration of NH₄F (straight black line). The graph also shows the range of wt % NH₄F in which complete anodization of Ti foil of varying thickness occurs for a given concentration of water according to one aspect of the present invention.

FIG. 2a shows an FESEM image of the top half of a completely anodized Ti foil sample (The black line seen towards the bottom of FIG. 2a marks the separation between the two nanotube arrays shown in FIG. 3) according to an exemplary aspect of the present invention.

FIG. 2b shows an FESEM image of a cross-section of a fractured sample of the nanotube array of the present invention.

FIG. 3 shows an FESEM image of the top and bottom half of the self-standing titania membrane of the present invention.

FIG. 4a shows a TEM image of nanotube crystallized at 580° C. according to an exemplary aspect of the present invention.

FIG. 4b shows a selected area diffraction pattern showing the anatase phase of the nanotube array according to one aspect of the present invention.

FIG. 5a shows a low magnification FESEM image of the nanotube array chemically etched to form a flow-through membrane according to an exemplary aspect of the present invention.

FIG. 5b shows a high magnification FESEM image of a partially etched barrier layer of the nanotube array of the present invention.

FIG. 5c shows a high magnification FESEM image of the bottom of a fully opened nanotube array of the present invention.

FIG. 5d shows a high magnification FESEM image of the top of a fully opened nanotube array of the present invention.

FIG. 6a shows another FESEM image of the nanotube array with an inset showing a high magnification image of the same according to one aspect of the present invention.

FIG. 6b shows an FESEM image of a cross section for the nanotube membrane with an inset showing a high magnification image of the same.

FIG. 6c shows a high magnification FESEM cross sectional image of a mechanically fractured sample of the nanotube array of the present invention.

FIG. 7a shows a high magnification FESEM image of a back (barrier layer) side of an as-fabricated nanotube array according to one aspect of the present invention.

FIG. 7b shows a high magnification FESEM image of a partially etched back (barrier layer) side of the as-fabricated nanotube array.

FIG. 7c shows a high magnification FESEM image of a fully etched back (barrier layer) side of the as-fabricated nanotube array.

FIG. 8 shows an FESEM image of the nanowires occasionally formed on the surface of the self-standing titania nanotubular/porous membrane upon critical point drying according to an exemplary aspect of the present invention.

FIG. 9a shows a digital image of a titania nanotube array on titanium foil (as-anodized) according to an exemplary aspect of the present invention.

FIG. 9b shows a digital image of flat membranes kept in ethyl alcohol after separation from titanium foil and etching of the barrier layer.

FIG. 9c shows a digital image of membranes taken directly from water/ethanol and dried.

FIG. 9d shows a digital image of flat membranes obtained after critical point drying according to one aspect of the present invention.

FIG. 10 shows a GAXRD pattern of an annealed nanotube-array sample exhibiting anatase peaks according to one aspect of the present invention.

FIG. 11 shows a high magnification FESEM image of the surface of a self-standing, mechanically robust TiO₂ membrane after annealing according to an exemplary aspect of the present invention.

FIG. 12 shows a digital image of a cylindrical TiO₂ nanoporous membrane, in air, made by anodization of an outer diameter piece of Ti tubing according to an exemplary aspect of the present invention.

FIG. 13 illustrates a solar cell using the titania nanotube array of the present invention.

FIG. 14 is a schematic drawing of an experimental setup for biofiltration using the TiO₂ membranes of the present invention.

FIG. 15 shows a plot of time dependent diffusion of glucose through a titania membrane according to an exemplary aspect of the present invention.

### DETAILED DESCRIPTION OF THE PREFERRED EMBODIMENT

Fabrication of highly ordered, high aspect ratio semiconducting metal oxide nanotubes of great lengths is key to boosting the performance of a variety of nanotube-based or adaptable devices and technologies. Herein is provided a simple, robust chemical anodization fabrication route for achieving ultrahigh surface area vertically oriented TiO₂ nanotubes having a high aspect ratio and length of at least 10 μm. Membranes of such ultra long nanotube array with both sides open form a new generation of structure for use in bio-filtration, solar cells, implants and catalytic membrane in fuel cells. The nanotube array, whether flat or cylindrical, exhibit a large-area and uniform pore size; thus, the nanotube array of the present invention are highly suitable for any of the above applications and even more considering all technology areas that would benefit from the characteristics exhibited by the TiO₂ nanotubes of the present invention. Having shown the ability to separate the array as individual nanotubes, the present invention suggests the possibility of achieving electrically assembled nanotube arrays for use in a variety of other applications.

Arrays of TiO₂ nanotubes fabricated by anodization constitute a vertically oriented self-organized architecture. The vertical orientation of the array is ideal in many applications such as dye-sensitized solar cells and photocatalytics. In the case of dye-sensitized solar cells, the vertical orientation discourages recombination of electrons and facilitates electron flow to the contact, With photocatalytics, such as photolysis, the vertical orientation facilitates hydrogen gas travel from the individual tubes. TiO₂ nanotubes have many unique advantages. One advantage is the increase in effective internal surface area without a decrease in geometric and structural order. The second advantage is the ability to influence the absorption and propagation of light through the architecture by precisely designing and controlling the geometric parameters of the architecture. Another key advantage is that the aligned porosity, crystallinity and oriented nature of the nanotube array make them attractive electron percolation pathways for vectorial charge transfer between interfaces. For applications where vertically oriented titania nanotubes have been integrated, these advantages have manifest themselves in an extraordinary enhancement of the extant TiO2 properties.

One area the present invention seeks to enhance with the integration of highly ordered, high aspect ratio nanotube arrays is dye-sensitized solar cells (DSSCs). Currently, the efficiency of DSSCs based on crystalline nanoparticulate semiconducting metal oxide films is limited by poor absorption of low energy photons in the red and near infrared. The use of thicker nanocrystalline films is counteracted by the slow electron diffusion through the random nanoparticulate network. Among one dimensional architectures, nanotube arrays have a higher geometric surface area due to the additional surface area enclosed inside the hollow structure. The most important geometrical parameters of the nanotube architecture are the pore diameter, wall thickness and the nanotube length which represents the thickness of the nanotube array grown vertically-oriented on a substrate. For a given pore diameter and wall thickness, the internal surface areas increases almost linearly with nanotube length.

To date, earlier generation TiO₂ nanotube arrays could not be grown to sufficient lengths to leverage the higher geometric surface area associated with the array. Further improvement in the length of the array requires enhancements of the field-assisted rate at which the Ti—Ti0₂ interface moves into the Ti metal. At first glance, enhancing the rate of the field-assisted Ti—Ti0₂ would appear to warrant an increase in the electric field, however, large electric fields can result in a thicker barrier layer that retards the transport of Ti⁴⁺ ions outward from the titanium substrate and the inward transport of OH⁻ and O²⁻ ions. Furthermore, in aqueous electrolytes containing a large concentration of ions, the Ti0₂ barrier layer experiences dielectric breakdown beyond a threshold level of the electric field. Subsequent to dielectric breakdown, electronic conduction instead of the desirable ionic conduction contributes to almost all the anodization current. The present invention mitigates these effects by eliminating the water content of the electrolytes to less than 5% which allows for thinner or lower quality barrier layers through which ionic transport may be enhanced. Further, the higher breakdown potential of the oxide in non-aqueous electrolytes allows for a wider range of anodization-potentials over which nanotube formation occurs. For example, formamide and N-methylformamide are highly polar, with dielectric constants of 111 and 182.4 respectively, much greater than that of water which has a dielectric constant of 78.39. For a given potential, higher electrolyte capacitance induces more charges to be formed on the oxide layer improving extraction of the TiO⁴⁺ ions, while the higher electrolute polarity allows hydrofluoric acid (HF) to be easily dissolved facilitating its availability at the TiO₂-electrolyte interface. In the case of organic electrolytes, the donation of oxygen is more difficult in comparison to water, thus reducing the tendency to form oxide. At the same time, the reduction in water content reduces the chemical dissolution of the oxide in the fluorine containing electrolytes and hence aids in the longer-nanotube formation.

### Method

Therefore, by way of example and resulting from experimentation, a method of achieving maximum nanotube growth is described hereinafter. According to one exemplary aspect of the present invention, titanium foil of varying thicknesses, such as for example 0.25, 0.5, 1.0 and 2.0 mm thick samples, cleansed with acetone followed by an isopropyl alcohol rinse before anodization. Although specific thicknesses are referenced it should be appreciated that the foil can be of any thickness amenable to anodization. The present invention appreciates that the thickness for formed oxide is a function of thickness for the working electrode, such as for example the thickness of the titanium foil/film. The titanium foils of the present invention constitute “thick films” as is commonly appreciated and known by skilled artisans. The titanium foils have a sufficient thickness to provide enough rigidity and stability to be handled and to facilitate anodization. The titanium foils are of high grade titanium. The present invention is not limited to anodization of only pure titanium foils (such as 99.99% pure; Alfa Aesar, Ward Hill, Mass.). For example, the anodization process of the present invention is still operable in foils having impurities, such as for example, foils comprising 40-50% Ti. In another aspect of the present invention, Titanium-Iron (Te—Fe) and Titanium-Copper (Ti—Cu) films are provided by co-sputtering the two onto a substrate, such as an electrically conductive substrate.

The anodization was performed in a two-electrode configuration with titanium foil as the working electrode and platinum foil as the counter electrode, under constant potential at room temperature, approximately 22° C. Although anodization was performed at room temperature, it should be appreciated that anodization could occur over a variety of temperatures. For example, anodization could be performed from −5 degrees Celsius to 100 degrees Celsius or any other temperature range amenable to anodization for forming the nanotube array of varying geometries and morphology of the present invention. An electrolytic bath is used to anodize titanium foil providing synthesis of self-aligned, hexagonally packed, self-standing nanotube arrays in excess of 10 μm in length, such as nanotube arrays ranging anywhere from 10 μm to in excess of 1000 μm Skilled artisans will recognize that there are alternative packing arrangements in lieu of the preferred hexagonal arrangement the titania nanotube array of the present invention. However, as compared to other perceivable packing arrangements, the hexagonal arrangement provides superior structural integrity of the array and best closes the gaps between adjacent tubes within the nanotube array. Limiting the gap between adjacent tubes in the array limits unwanted materials from entering and introducing imperfections into the array. Those skilled in the art can appreciate that the electrolyte may be an aqueous solution such as an amide based electrolyte or a non-aqueous electrolyte such as a polar organic electrolyte. The time-dependent anodization current may be recorded using a computer controlled multimeter and the as-anodized samples ultrasonically cleansed in deionized water to remove surface debris. The morphology of the anodized samples can be studied using a field emission scanning electron microscope (FESEM).

As reported herein, ethylene glycol (EG) as a solvent in electrochemical oxidation exhibits an extremely rapid titania nanotube growth rate of up to 15 μm/min [20], which is nearly five times the maximum rate of nanotube formation in amide based electrolytes [9] and over an order of magnitude greater than the growth rate in aqueous solutions [16]. The nanotubes formed in EG exhibited long range order manifested in hexagonal close-packing and very high aspect ratios (6000). The higher aspect ratio is beneficial in many applications. In particular, high aspect ratios facilitate vectorial charge transport in solar cell applications using the titania nanotube array of the present invention. EG was also found to minimize lateral etching of the nanotube array. As such, the nanotube array exhibited uniform wall and pore thickness, unlike the as-anodized nanotubes anodized in other aqueous electrolytes that dissolve the walls and pores of the tube more at the top of the sample than at the bottom due to the top-up formation of the tube (i.e., the top portion of the nanotube is in the electrolyte solution longer and is exposed to the dissolving affects of the electrolyte for longer than the bottom portion). In one example, to control this dissolution reaction, the H+ ion concentration was reduced by limiting the water content to the level of water contained in HF containing solution. This water ensured the field assisted etching of the Ti foil at the pore bottom, and additionally, protophilic DMSO accepts a proton from HF, reducing its activity. This allowed the DMSO nanotubes to grow deep into the titanium foil without any significant loss from the pore mouth. The presence of DMSO modifies the space charge region in the pores, thereby avoiding the lateral etching as well, leading to the steady pore growth and low chemical etching of the nanotube walls. For example, in one exemplary aspect of the present invention, the nanotube array was obtained using an EG electrolyte containing a sufficient wt % NH₄F and H₂O upon anodizing showed an efficiency for TiO₂ formation close to 100% after accounting for the porosity of the structure and the titanium dioxide dissolved during the formation of the nanotubular structure, which indicates that no side-reactions and negligible bulk chemical dissolution of formed TiO₂ nanotube arrays occurred during the anodization process. Reusing the solution after anodization exhibited the growth of passive oxide of few hundred nanometers with no nanotube formation, which could only be restored upon the addition of NH₄F and ethylene glycol. This finding strongly suggests that depletion of H^{±} and F⁻ species in the used solution renders it unable to produce sufficient local acidification at the pore bottom to limit the barrier layer thickness. Thus, in non-thickness limited growth of the oxide in a fluoride containing organic electrolyte, the nanotube array length is limited by the availability of fluoride and hydroxyl ions. The ion concentration of the electrolyte is not the only anodization variable. Other important anodization variables include for example, voltage, anodization time, water content, and previous use of the electrolyte. All of these anodization variables can be combined to achieve nanotube arrays with length and morphology amenable to various discrete applications. Therefore, the challenge in obtaining longer nanotubes, limited only by the complete anodization of the starting Ti foil, is in obtaining the optimum growth rate by manipulating at least the electrolytic composition and duration, and other anodization variables introduced above and detailed in the proceeding description.

Although EG is highly amenable to electrochemical oxidation, it should be appreciated that the present invention is not limited to the use of electrolytes containing solely EG, the present invention contemplates the use of other polar organic electrolytes, such as for example formamide (FA), dimethyl sulfoxide (DMSO), Dimethylformamide (DMF), and N-methylformamide (NMF) to provide fluoride ions. The present invention contemplates in another exemplary aspect, the fabrication of vertically oriented TiO₂ nanotube arrays using an electrolyte of DMSO containing either hydrofluoric acid (HF), potassium fluoride (KF), or ammonium fluoride (NH₄F) [23]. Skilled artisans can appreciate that there are alternatives to such chemicals as HF. Using electrolytes having sufficient fluoride ions, such as NH₄F, provide adequate etching of the Ti0₂. For example, nanotubes may be achieved having a length in excess of 101 μm, inner diameter 150 nm, and wall thickness 15 nm for a calculated geometric area of 3, 475 using an anodization potential of 60 V with an electrolyte of 2% HF in DMSO for a duration of 70 hours. The weak adhesion of the DMSO fabricated nanotubes to the underlying oxide barrier layer and low tube-to-tube adhesion facilitates their separation for applications where dispersed nanotube array are desired.

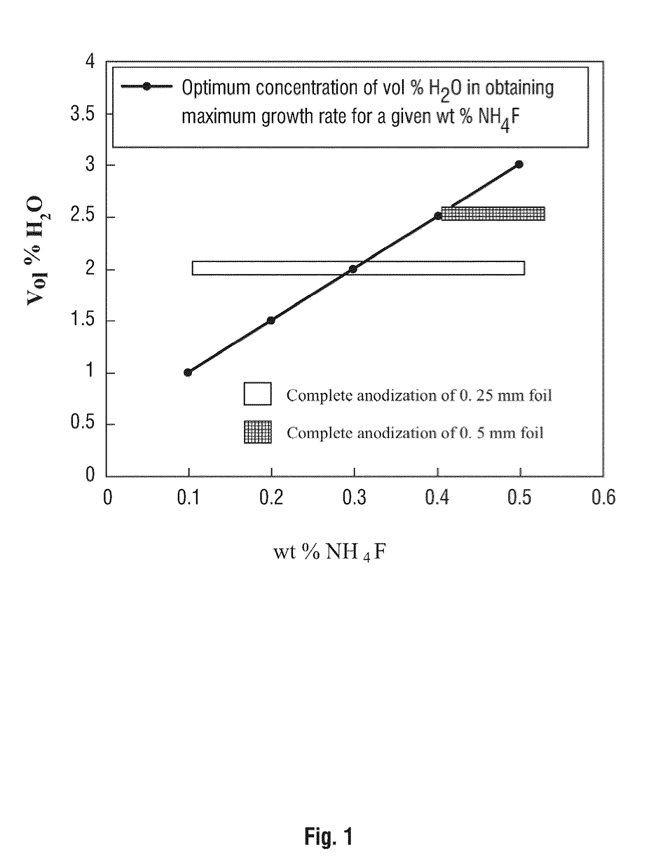

For ethylene glycol electrolytes a maximum nanotube growth rate was observed at 60 V [20]. A study of the anodization of varying thickness Ti foils, such as 0.25 to 2.0 mm thick Ti foils, in electrolytes containing different concentrations of NH₄F and H₂O in EG at 60 V was also conducted. The optimum concentration of water for achieving the highest growth rates for different NH₄F concentrations follows a pattern shown in FIG. 1. In the given range of NH₄F and H₂O concentrations, the anodic dissolution due to the increased wt % of NH₄F is compensated by the increase in H₂O concentration and results in greater growth rates and hence a longer nanotube length. FIG. 1 also shows, by way of example, the range of H₂O and NH₄F concentrations for which complete anodization (utilization) of 0.25 mm and 0.5 mm Ti foil samples are achieved as illustrated in the following Examples which are merely exemplary in nature of the various electrolytic compositions.

### Example 1

In one exemplary characterization of the present invention, using 0.1 wt %-0.5 wt % NH₄F with 2% water, 0.25 mm foil samples were completely anodized resulting in two 320 to 360 μm nanotube arrays across a thin barrier layer.

### Example 2

In another exemplary characterization of the present invention, nanotube arrays were obtained using a solution containing 0.3 wt % NH₄F and 2% H₂O in EG for 96 hours. Anodizing 0.5 mm titanium foil in an identical electrolyte for 168 hours (7 days), the maximum thickness obtained was ±380 μm, suggesting complete utilization of the active electrolyte species.

### Example 3

In still another exemplary characterization of the present invention, complete anodization of a 0.5 mm foil was achieved in an electrolyte containing 0.4-0.6% NH₄F and 2.5% H₂O in EG (See FIG. 1); the resulting length of nanotube array on each side of the oxidized substrate was found to be 538 μm. The 538 μm was attained by completely anodizing the 0.5 mm titanium foil at 60V for 168 hours in 0.4 wt % NH₄F and 2.5% water in EG.

### Example 4

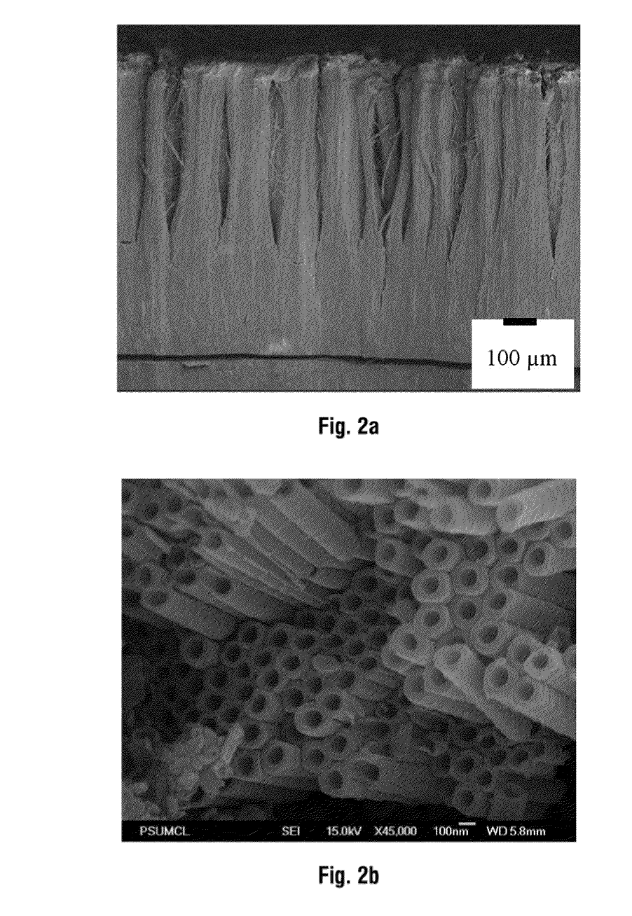

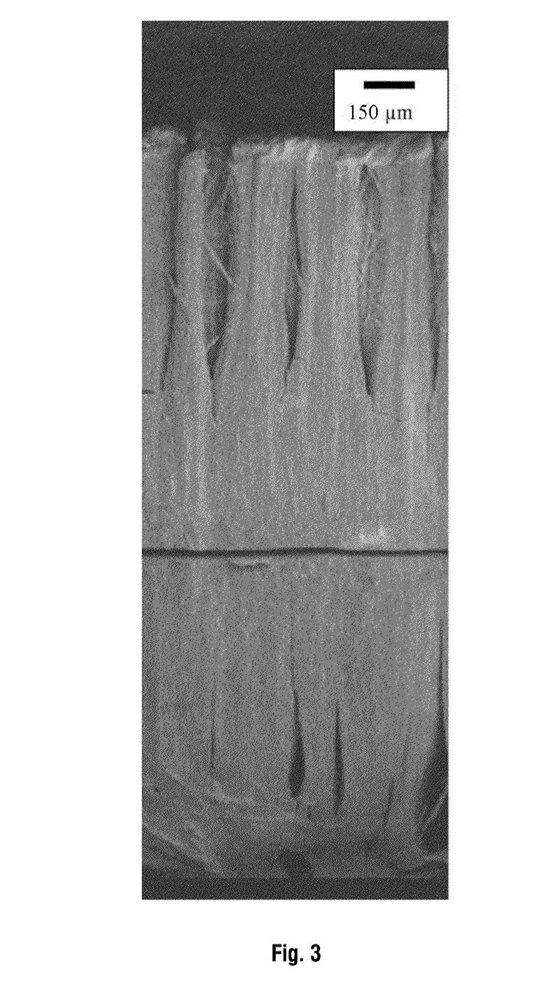

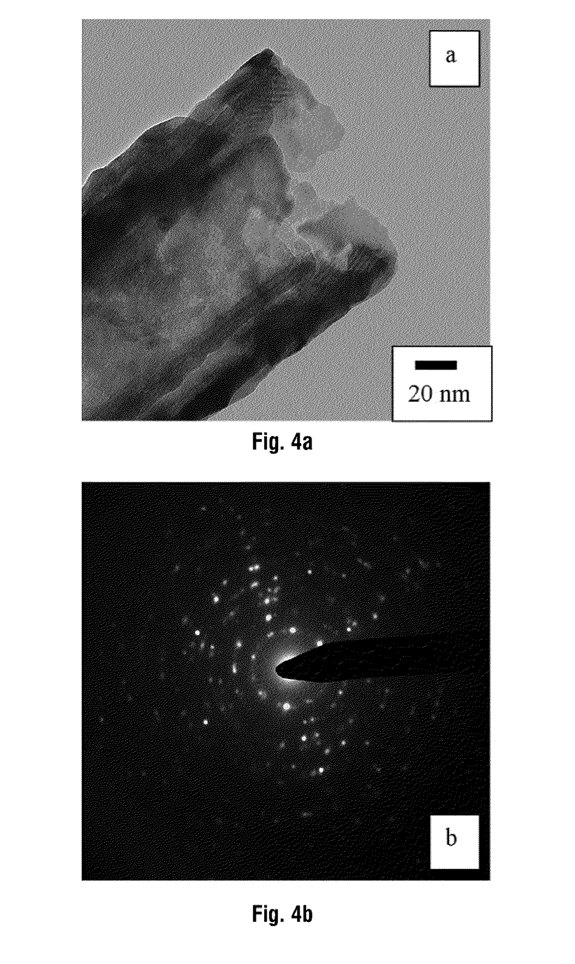

In yet another exemplary aspect of the present invention, a nanotube array length in excess of 1000 μm was obtained upon anodizing 2.0 mm thick Ti foil at 60 V for 216 hours (9 days) in 0.5 wt % NH₄F and 3.0% water in EG (See FIGS. 2a and 2b). The foil, which was anodized on both sides of the basal plane (The black line seen towards the bottom of FIG. 2a marks the separation between the two nanotube arrays or the basal plane.) simultaneously, formed a self-standing nanotube array of over 2 mm in thickness, as shown in FIG. 3. The anodized structure was annealed in oxygen ambient at 580° C. for 3 hours at a ramp rate of 1° C./min. Glancing Angle X-Ray Diffraction (GAXRD) and Transmission Electron Microscopy (TEM) analysis revealed the nanotubes to be anatase. FIG. 4a shows the TEM image of the crystallized nanotube, with the diffraction pattern shown in FIG. 4b confirming the presence of anatase, a naturally occurring crystalline form of titanium dioxide, TiO2.

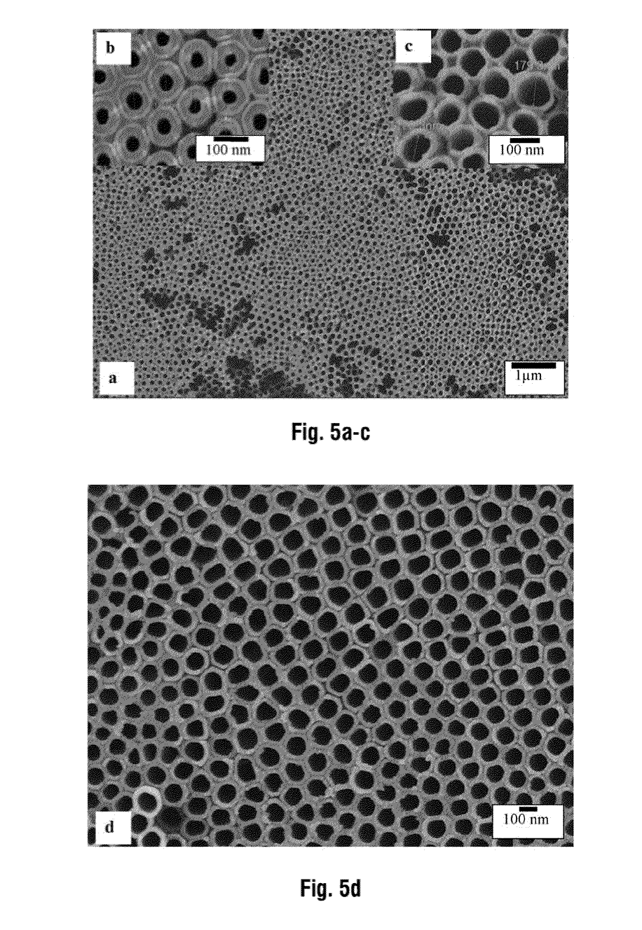

As-fabricated nanotube arrays have one end open with the opposite end being closed; the opposite end is where the tube is formed by electrochemical etching of the titanium foil. In one exemplary aspect of the present invention, a 2.0% HF in water mixture may be used to the treat the closed-side of a self-standing membrane for several minutes to remove the plug. FIG. 5a-d shows multiple images of a back-side etched sample. Specifically, FIG. 5a shows a partial opening after a 1 minute etch, FIG. 5b shows a complete opening after a 2 minute etch, FIG. 5c shows a fully opened array bottom, and, FIG. 5d shows the top surface of an as-anodized nanotube array sample.

Surface area measurements were also performed. In one aspect of the present invention, dry TiO₂ nanotube array membranes were evacuated to 2 mm Hg pressure and the physical adsorption of nitrogen gas measured at 77.35K. An adsorption isotherm was recorded as volume of gas adsorbed (cc/g @ STP) versus relative pressure. The BET (Brunauer, Emmett and Teller) equation was used to obtain the volume of gas needed to form a monolayer on the surface of the sample. The actual surface area was calculated from the known size and number of the adsorbed gas molecules. Table 1, below, shows the surface area and the pore volume for samples of different inner pore diameter (40 V, 70 nm inner pore diameter, 12 μm length, 0.3% NH₄F and 2% H₂O, 6 hours; 60 V, 18 μm length, 0.3% NH₄F, 2% H₂O, 6 hours).

| | | | Inner diameter |
|---|---|---|---|
| | BET surface | Pore volume | measured from |
| | area (m²/g) | (cm³/g) | SEM (nm) |
| Ti foil | 1.9 | 0.001 | — |
| 40 V | 38 | 0.181639 | 70 |
| 60 V | 36 | 0.212449 | 105 |

From Table 1, one may infer that surface area is pore size/volume dependent. The BET surface area measurements show, respectively, an average surface area of 38 m²/g and 36 m²/g for the 70 nm and 105 nm inner diameter nanotube arrays.

The preceding demonstrates the synthesis of TiO₂ nanotube arrays in excess of 1000 μm in length by anodic oxidation, with a free-standing membrane thickness in excess of 2 mm. Depending upon the starting thickness of the Ti foil sample, bath conditions, such as for example wt % NH₄F and H₂O concentration in ethylene glycol, may be varied to achieve complete anodization of the foil sample. As identified above, the present invention appreciates that further altering of the batch conditions could provide complete anodization of foil samples, such as Ti, having even greater thicknesses, perhaps well in advance of 2.0 mm. Thus, the present invention, through controlled anodization by holding in equilibrium the processes of electrochemical oxidation, electrochemical dissolution and chemical dissolution, provides the anodic formation of nanoporous and nanotubular structures of lengths previously unattained. In addition, by maintaining dynamic equilibrium between growth and dissolution processes, the structural characteristics of the nanotube array, including individual nanotube dimensions such as pore size, wall thickness, length, tube-to-tube connectivity, and crystallinity may be controlled. The present invention holds that by maintaining dynamic equilibrium between growth and dissolution processes the conversion efficiencies of the titanium foil to titanium oxide can approach 100 percent.

### Example 5

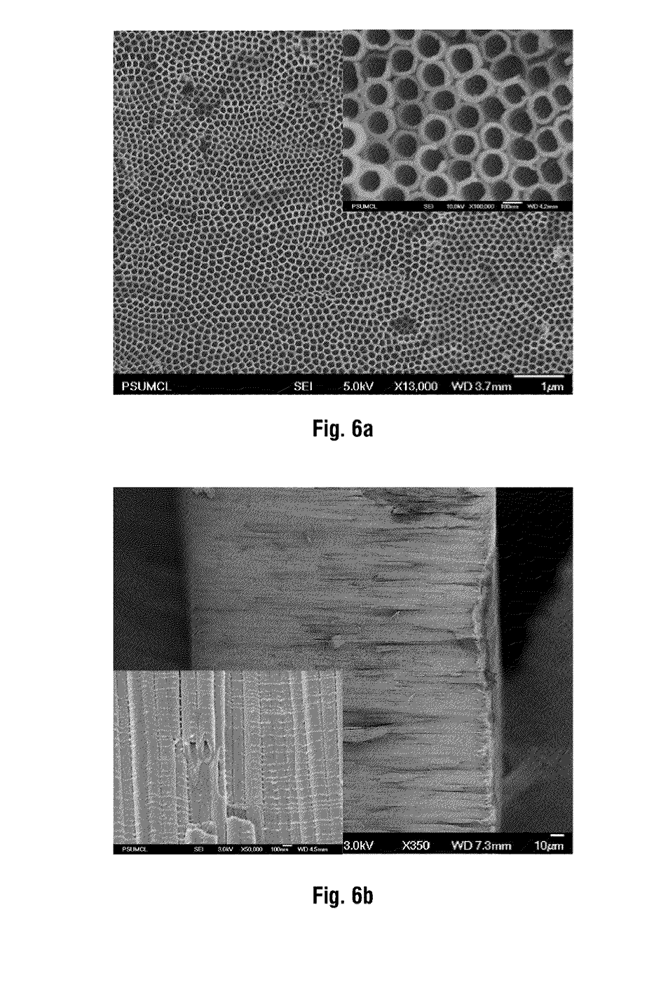

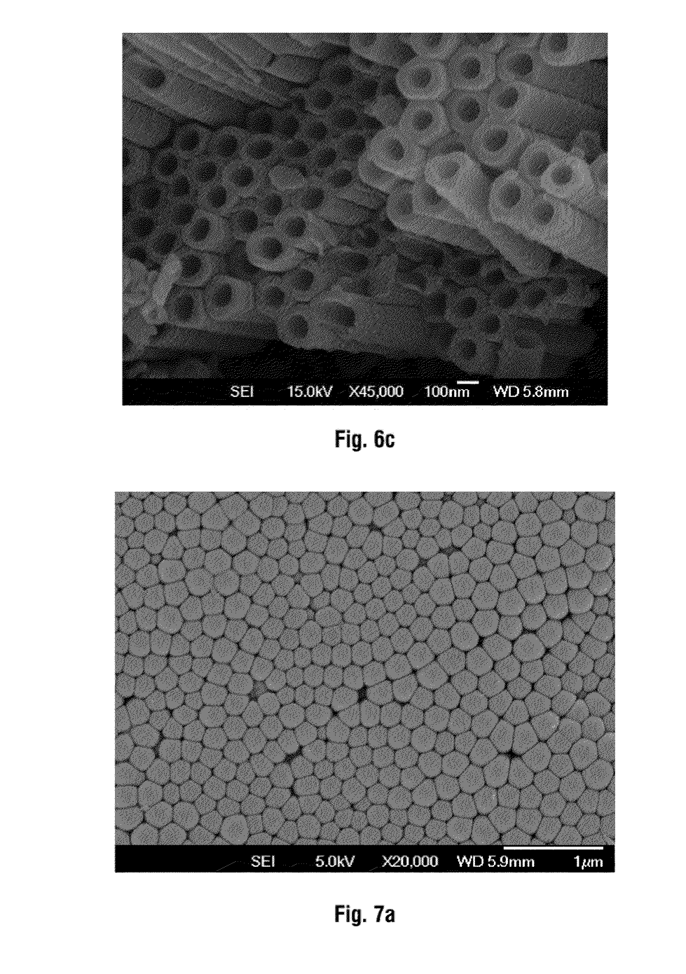

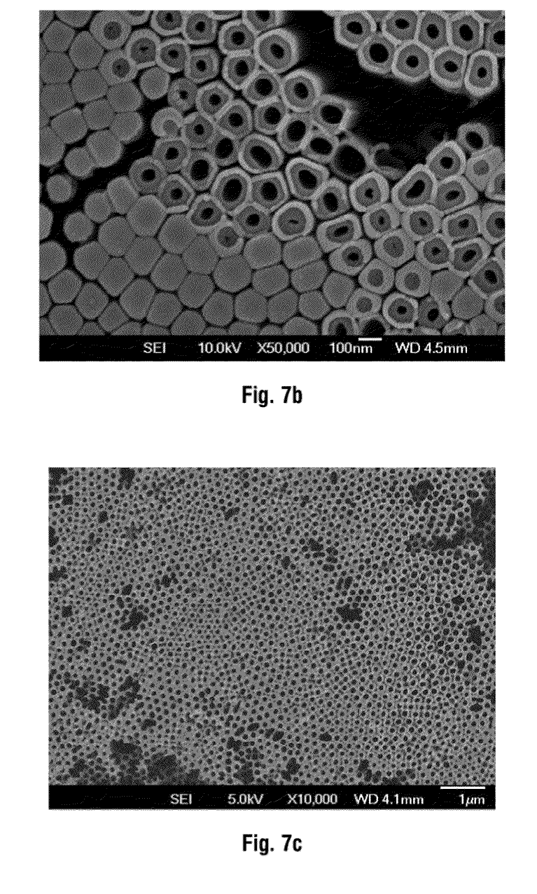

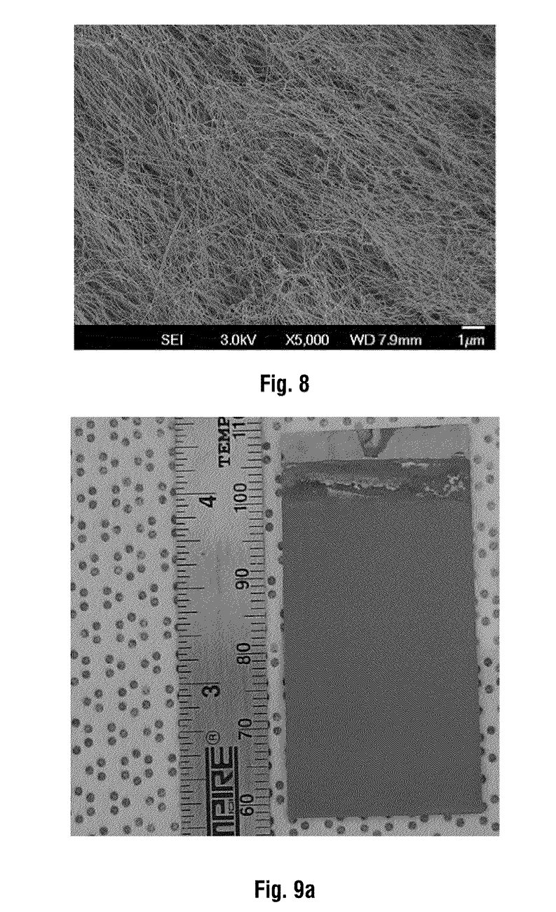

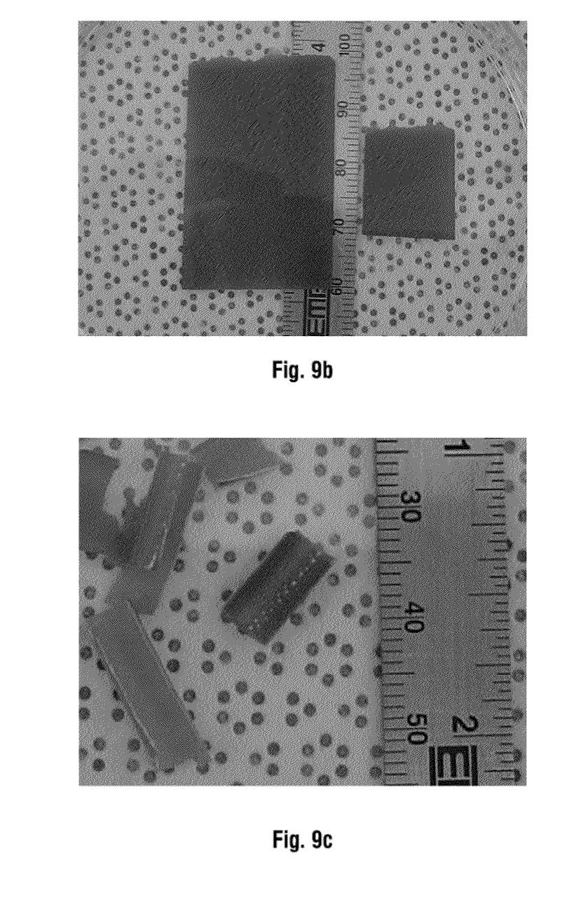

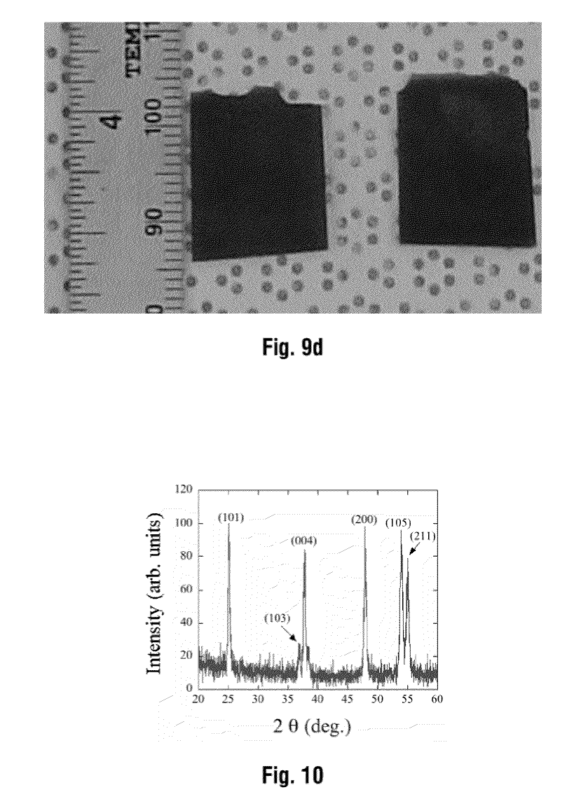

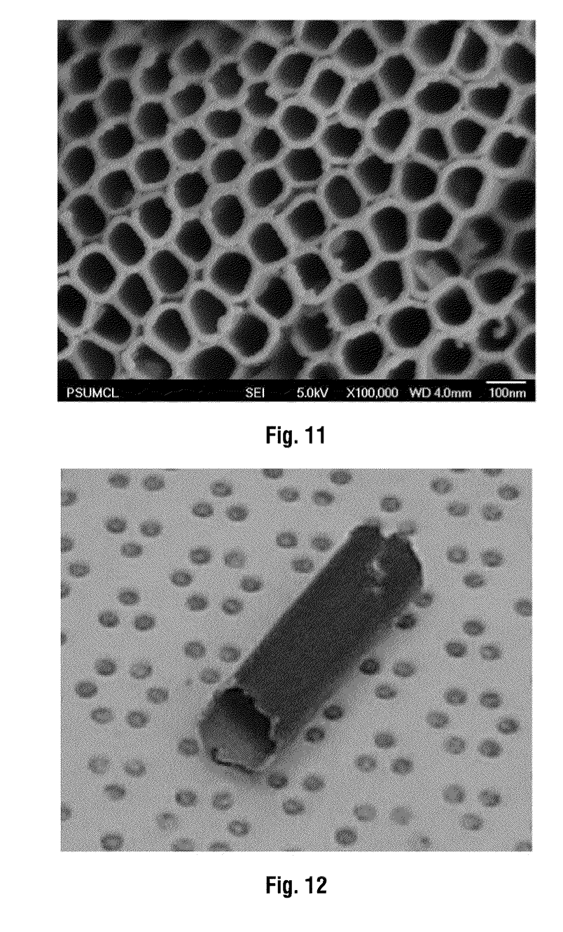

In another exemplary characterization of the present invention, flat array membranes are fabricated for discrete applications, such as for example filtering biological species [26], using titanium foils of varying thickness. The Ti foils are prepared for anodization, which may include one or more of the steps of ultrasonically cleansing them with dilute micro-90 solution, rinsing in de-ionized water and ethanol, and drying in nitrogen. To fabricate the flat array membrane, an electrolyte composition of 0.3 wt % ammonium fluoride and 2 vol. % water in ethylene glycol may be used. Anodization can be performed at room temperature (˜22 degrees Celsius) with a platinum foil cathode. A dc power supply, being used as the voltage source, may be used to drive the anodization process. A multimeter may be used to measure the resulting current. A nanotube length of about 220 μm (pore size 125 nm, standard deviation 10 nm) was obtained when anodization was performed at 60 V for a duration of 72 hours. The as-anodized samples were dipped in ethyl alcohol and subjected to ultrasonic agitation till the nanotube array film was separated from the underlying Ti substrate. The compressive stress at the barrier layer-metal interface facilitates detachment from the substrate. Those skilled in the art can appreciate that other means exist to detach the nanotube array from the substrate, such as for example, by voltage pulsing the as-anodized sample, or simply by mechanically or manually detaching the substrate from the nanotube array. FIGS. 6a and 6b show FESEM images of the membrane top surface and cross section at varying degrees of magnification, while FIG. 6c shows a cross-sectional image of a mechanically fractured sample. FIG. 7a shows the backside, i.e. the barrier layer side of the as-fabricated nanotube array film. Since the nanotube array is formed from the closed end by electrochemical etching of the titanium foil the need arises to open the closed end; in one aspect of the present invention, this is accomplished using a dilute hydrofluoric acid/sulfuric acid solution applied to the barrier layer side of the membrane for etching the oxide. The oxide is then rinsed with ethyl alcohol. FIG. 7b shows a partially opened back-side. The acid rinse is repeated until the pores are completely opened as seen in FIG. 7c, after which the membrane is ultrasonically cleansed to remove any etching associated debris. The (initially flat) membranes significantly curled (See FIG. 9c) after they were removed from the liquid and dried in air making them unsuitable for filtering applications. The surface tension forces of the solution acting on the membrane were mainly responsible for this behavior, hence a low surface tension liquid such as hexamethyldisilizane (HMDS) was used to wash the membrane. Although this reduced the problem to an extent, the real breakthrough came when a method called critical point drying was used to remove the solution from the membrane. The membrane flatness is preserved when dried in a critical point dryer with carbon dioxide, as best illustrated in FIG. 9d. The surface of the membrane after critical point drying occasionally showed a nanofiber surface (See FIG. 8) which could be removed by subjecting the membrane to ultrasonic agitation. FIGS. 9a-d illustrate the following: FIG. 9a shows a 200 μm thick nanotube array film on titanium foil substrate after anodization and cleaning; FIG. 9b shows the membrane immersed in ethyl alcohol after it was separated from the underlying Ti substrate by ultrasonic agitation, and the barrier layer removed by chemical etching; FIG. 9c shows the membranes taken directly out of solution and then dried (note the extensive curling); and FIG. 9d shows the flat membranes obtained after critical point drying. It should be noted that membranes of area ˜2.5 cm×5 cm may be fabricated where an upper size limit may be dictated by the capacity of the CO₂ critical point drying instrument; regardless, the technique can be readily adapted to fabricate much larger area membranes. Membranes 40 μm thick or thicker were found robust enough for easy handling. For example, self-standing, but quite fragile, membranes having a minimum 4.4 μm thickness may be fabricated. The resulting as-fabricated membranes of the present invention have an amorphous structure. It is known that crystallinity is essential for any application involving electrical charge carrier generation and transport/transfer, including in photocatalytic cleaning, water photoelectrolysis, and solar cells [6, 28, 25]. Thus, the membranes were crystallized via low temperature annealing to prevent disruption of the flatness of the membrane. The membranes were readily crystallized into an anatase phase, See FIG. 10, by annealing in an oxygen environment at 280° C. for 1 hour; GAXRD patterns were recorded using a diffractometer. The surface of the membrane after annealing is shown in FIG. 11.

FIG. 12 shows a fabricated cylindrical TiO₂ nanotube array membrane by the complete anodization of hollow Ti tubing Like their flat membrane counter-parts, the cylindrical membranes fared best when dried via critical point drying, and could be crystallized by a low temperature anneal.

### Applications

One application that benefits from the present invention, as mentioned above, is solar energy. Solar energy is a clean and renewable energy source that is accessible virtually everywhere on earth. However, it is not a viable energy source for many applications because its cost per unit energy is prohibitively high compared to existing energy sources. The primary cost to traditional solar cells is the cost of the semiconductor, generally silicon, used to make the cells. The silicon must be highly purified and the refining process is energy intensive which results in a high cost for the final product. Silicon solar cells have photoconversion efficiencies (the ratio of total solar energy exposed to the cell to the total energy generated by the cell) of between 14-16% for the best commercially available devices, which are expensive to produce. Several factors contribute to a solar cell's photoconversion efficiency including the number of electrons generated and the rate of electron recombination. Thus, the present invention provides an improved dye-sensitized solar cell (DSSC) film which provides an efficient electron path, has a high surface area, and can be grown to lengths which result in photo conversion efficiencies exceeding that of silicon based solar cells.

### Solar Cells

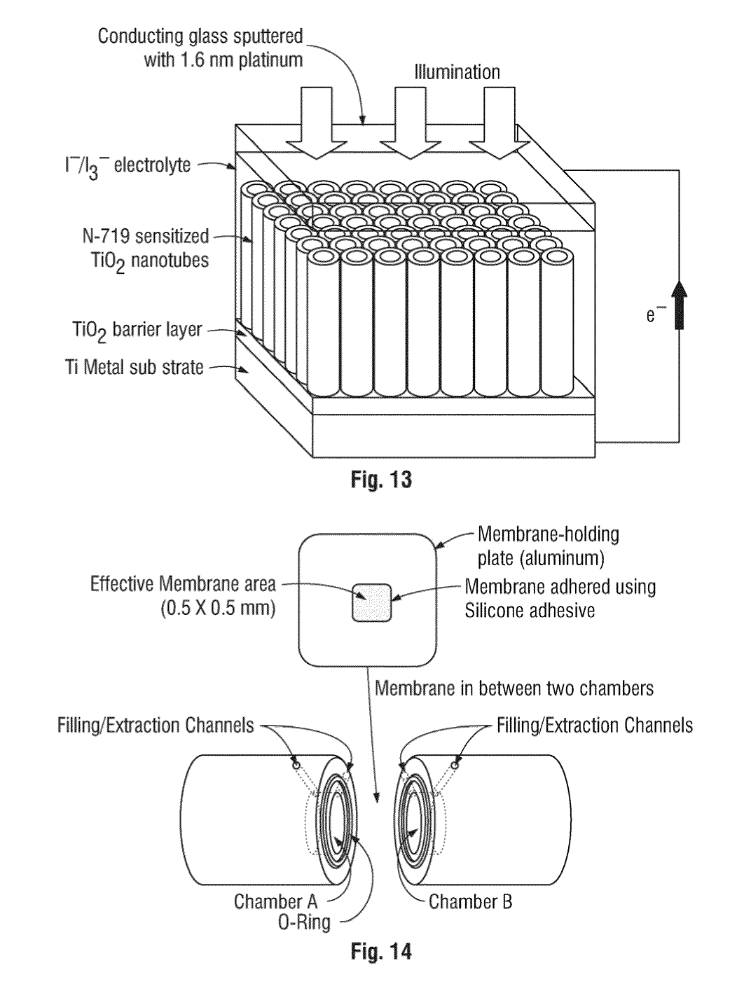

Dye-sensitized solar cells are a low cost alternative to traditional silicon based solar cells. DSSCs such as the TiO₂ solar cell illustrated in FIG. 13 can be constructed from low cost materials at a fraction of the price of traditional silicon solar cells. Generally, DSSCs are comprised of a crystalline nanoparticulate film deposited on a transparent conductor. The film is coated in a photosensitive dye which adheres to the surface of the crystalline nanoparticulate film. A layer of conductive material is coated with an electrolyte and affixed to the film side of the transparent conductive material. The cell functions by allowing light to pass through the transparent conductor and strike the photosensitive dye. When a photon impacts the dye, the dye generates an electron which is passed to the conduction band of the crystalline film. The dye recovers the lost electron from the electrolyte in a reaction that occurs much faster than the recombination time of the generated electron to prevent the electron from recombining with oxidized molecules of the dye. The oxidized electrolyte diffuses to a cathode where the cathode resupplies the electrolyte with an electron. The generated electron is transported through the conduction band of the crystalline film to the transparent conductor and then out of the cell.

The crystalline film is often comprised of a random network of nanoparticulates which do not provide efficient pathways for electrons to travel out of the film. The electrons traveling in the film move slowly due to collisions and scattering in the random network of nanoparticulates and this results in a significant portion of the electrons recombining. This type of solar cell also suffers from poor electron generation from low energy photons in the red and near infrared wavelengths. More electrons can be generated by increasing the crystalline film thickness and thereby increasing the active surface area exposed to photons. However, the increased electron generation from the increased film thickness is negated by increased electron recombination due to the longer path the electron must travel to exit the film.

One proposed solution to this problem is to create a film comprised of columnar structures instead of a random nanoparticulate network. Nanowires are a more efficient pathway than a random network of nanoparticulates and reduce electron loss from recombination. However, nanowires have greatly reduced surface area than the random network of nanoparticulates (on the order of ⅕th the active surface area) and so has a greatly reduced electron generation which negates the benefit of the improved pathway. Another proposed solution is to create a film of nanotubes. The tubes have a higher geometric surface area than nanowires due to the additional surface area of the hollow tube structure, but cannot be grown to a thickness necessary for a photoconversion efficiency competitive with silicon based devices. Therefore, there is a need in the art for an improved DSSC film which provides an efficient electron path, has a high surface area, and can be grown to lengths which result in photo conversion efficiencies exceeding that of silicon based solar cells.

In an exemplary characterization of the applications of the present invention, a DSSC comprised of a layer of titanium sputtered on a piece of conductive glass. The glass is dipped in an acid bath charged with a mild electric current and the combination of acid and oxygen etches the metal into an array of TiO2 nanotubes. The conductive glass with the nanotubes is heated in oxygen until the nanotubes crystallize and become transparent. The tubes are coated with a photosensitive dye which bonds to the surfaces of the nanotubes. Another conductive layer, coated with an electrolytic film is attached to the side of the conductive glass with the nanotubes.

### Example 7

In another exemplary characterization of the applications of the present invention, a novel method for fabrication of films comprised of vertically oriented Ti—Fe—O nanotube arrays on fluorine-doped tin oxide (FTO)-coated glass substrates by anodic oxidation of Ti—Fe metal films in an ethylene glycol+NH₄F solvent is disclosed. The photoconversion efficiency of TiO2 nanotube arrays under UV illumination are notable, 16.5% under 320-400 nm band illumination (100 mW/cm²). Since UV light accounts for only a small fraction of the solar spectrum, the potential for much higher photoconversion efficiencies are anticipated. For example, the photoconversion efficiency could be potentially as high as 18%. This high photoconversion efficiency is due in part to the efficient transportation path that the TiO2 nanotubes provide for generated electrons which greatly reduces or eliminates electron recombination within the tubes. The tubes can also be grown to great lengths which increases the active surface area resulting in increased electron generation. The cost of these devices is greatly reduced from prior art silicon devices because the cost of the materials is greatly reduced. This improved DSSC has photoconversion efficiencies rivaling existing silicon devices, while costing a fraction as much to produce. These benefits result in a much lower cost per unit energy and makes solar power a viable alternative for many applications.

### Biofiltration

In another exemplary characterization of applications of the present invention, titania nanotube membranes of 125 nm pore size and 200 μm thickness showed promise as a biofilter such as in glucose diffusion. Biofiltration membranes are typically comprised of polymers, however due to their wide pore size distribution their separation efficiency is significantly compromised. TiO₂ nanotube array membranes overcome these and other limitations of current polymeric biofiltration membrane technologies.

FIG. 14 illustrates the apparatus used for diffusion studies. The membrane was adhered with a cyanoacrylate adhesive to an aluminum frame as shown in the figure, then sealed between the two diffusion chambers. Chamber A was filled with 2 ml of 1 mg/ml glucose solution and chamber B was filled with 2 ml of pure distilled H2O. The assembled setup was rotated at 4 rpm throughout the experiment to eliminate any boundary layer effects. Samples were collected from chamber B every 30 mins for up to 3 hrs. The concentration was measured by means of a quantitative enzymatic assay (Glucose GO, Sigma) and colorimetric reading via a spectrophotometer. The ratio of measured concentration (C) with original concentration (Co) was plotted against time to determine the diffusive transport through the membranes.

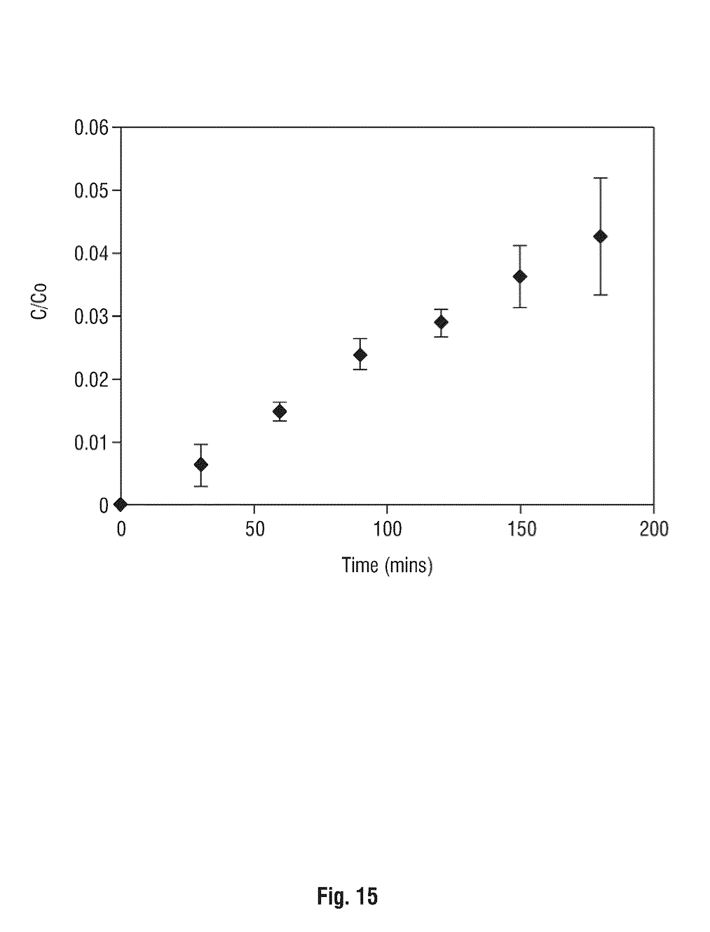

The process of glucose diffusion across a membrane separating two well-stirred compartments A and B can be described by Fick's first law of diffusion:

$$J = {D}_{eff} {A}_{eff} \frac{( {C}_{A} - {C}_{B} )}{L}$$

where J is mass flux, D_{eff} is the effective diffusion coefficient, A_{eff} is the cross-sectional pore area, L the membrane thickness, and C_{A} and C_{B} the measured concentrations, respectively, of chamber A (donor) and B (recipient). The flux can be considered steady state since over the course of the experiment compartment A acts as an infinite source of glucose with a negligible change in its concentration. FIG. 15 shows the measured B side concentration versus time; there is a high degree of linearity indicating a zero order diffusion system or zero order release profiles.

By coupling this with the mass balance equation, the diffusion coefficient can be calculated using the following expression:

$$- \frac{1}{2} ln ( \frac{{C}_{A 0} - 2 {C}_{B}}{{C}_{A 0}} ) = \frac{{A}_{eff} \cdot {D}_{eff} \cdot t}{Δ L \cdot V}$$

where C_{A0} is the initial concentration in chamber A, C_{B} the measured concentration in chamber B, ΔL the membrane thickness, V the total volume in chambers A and B, and t is time. The diffusion coefficients were then normalized by dividing D_{eff} by the diffusion coefficient in water, calculated according to Stokes-Einstein equation:

$$D = \frac{k \cdot T}{6 π \cdot η \cdot {R}_{d}}$$

where k is Boltzmann constant, T is temperature, η the solvent viscosity, and R_{d} the Stokes radius. We find the effective diffusion coefficient for glucose through the membrane (200 μm thick, 125 nm pore size) D_{eff}=1.28×10⁻⁶, that of water D_{H2O}=6.14×10⁻⁶, and the ratio D_{eff}/D_{H2O}=0.2.

The preferred embodiments of the present invention have been set forth in the drawings and specification and although specific terms are employed, these are used in the generically descriptive sense only and are not used for the purposes of limitation. Changes in the formed proportion of parts as well as in the substitution of equivalence are contemplated as circumstances may suggest or are rendered expedient without departing from the spirit and scope of the invention as further defined in the following claims.

### REFERENCES

All references listed throughout the Specification, including the references listed below, are herein incorporated by reference in their entireties.
1. G. K. Mor, K. Shankar, M. Paulose, O. K. Varghese, C. A. Grimes, Nano Letters 6 (2006) 215.
2. K. Zhu, N. R. Neale, A. Miedaner, A. J. Frank, Nano Letters 7 (2007) 69.
3. H. Wang, C. T. Yip, K. Y. Cheung, A. b. Djurisic, M. H. Xie, Y. H. Leung, W. K. Chan, Appl. Phys. Lett. 89 (2006) Article Number 023508 (3 pages).
4. K. Shankar, G. K. Mor, H. E. Prakasam, S. Yoriya, M. Paulose, O. K. Varghese, C. A. Grimes, Nanotechnology 18 (2007) Article Number 065707 (11 pages).
5. S. Uchida, R. Chiba, M. Tomiha, N. Masaki, M. Shirai, Electrochem. 70 (2002) 418.
6. G. K. Mor, K. Shankar, M. Paulose, O. K. Varghese, C. A. Grimes, Nano Letters 5 (2005) 191.
7. N. R. de Tacconi, C. R. Chenthamarakshan, G. Yogeeswaran, A. Watcharenwong, R. S. de Zoysa, N. A. Basit, K. J. Rajeshwar, Phys. Chem. B 110 (2006) 25347.
8. O. K. Varghese, M. Paulose, K. Shankar, G. K. Mor, C. A. Grimes, J. Nanosci. Nanotech. 5 (2005) 1158.
9. M. Paulose, K. Shankar, S. Yoriya, H. E. Prakasam, O. K. Varghese, G. K. Mor, T. J. Latempa, A. Fitzgerald, C. A. Grimes, J. Phys. Chem. B 110 (2006) 16179.
10. G. K. Mor, H. E. Prakasam, O. K. Varghese, K. Shankar, C. A. Grimes, Nano Lett. 7 (2007) Web Release Date: 3 Jul. 2007; DOI: 10.1021/n10710046.
11. H. L. Kuo, C. Y. Kuo, C. H. Liu, J. H. Chao, C. H. Lin, Catal. Lett. 113 (2007) 7.
12. Z. P. Zhu, Y. Zhou, H. W. Yu, T. Nomura, B. Fugetsu, Chem. Lett. 35 (2006) 890.
13. Q. Y. Cai, L. X. Yang, Y. Y. Yu, Thin Solid Films 515 (2006) 1802.
14. C. K. Xu, S. U. M. Khan, Electrochem. Solid State Lett. 10 (2007) B56.
15. C. A. Grimes, J. Mater. Chemistry 17 (2007) 1451.
16. G. K. Mor, O. K. Varghese, M. Paulose, K. Shankar, C. A. Grimes, Solar Energy Materials and Solar Cells 90 (2006) 2011.
17. G. K. Mor, O. K. Varghese, M. Paulose, C. A. Grimes, Sensor Letters 1 (2003) 42; O. K. Varghese, G. K. Mor, C. A. Grimes, M. Paulose, N. Mukherjee, J. Nanoscience Nanotechnology 4 (2004) 733.
18. M. Paulose, O. K. Varghese, G. K. Mor, C. A. Grimes, K. G. Ong, Nanotechnology 17 (2006) 398.
19. O. K. Varghese, X. Yang, J. Kendig, M. Paulose, K. Zeng, C. Palmer, K. G. Ong, C. A. Grimes, Sensor Letters 4 (2006) 120.
20. H. E. Prakasam, K. Shankar, M. Paulose, C. A. Grimes, J. Phys. Chem. C. 111 (2007) 7235.
21. K. Shankar, G. K. Mor, A. Fitzgerald, C. A. Grimes, J. Phys. Chem. C 111 (2007) 21.
22. V. P. Parkhutik, V. I. J. Shershulsky, Phys. D 25 (1992) 1258.
23. Yoriya et. al.,. Sensor Letters. Vol. 4, 3334-339 (2006).
24. Shankar et. al., Nature Materials, Jun. 2 (2006).
25. Mor et. al., Nanoletters. Vol. 6, No. 2, 215-218 (2006).
26. M. Paulose et. al., Large Area Biofiltration Membranes using Polycrystalline TiO₂ Nanotube Arrays, ACS Nano, Submitted Jul. 25 (2007).
27. Daoud, W. A.; Pang, G. K. H. J. Phys. Chem. B, Vol., 110, 25746-25750 (2006).
28. Mor, G. K.; Carvalho, M. A.; Varghese, O. K.; Pishko M. V.; Grimes, C. A., J. Mat. Res., Vol., 19, 628-634 (2004).

What is claimed is:

1. A method of forming a vertically oriented titania nanotube array using electrochemical oxidation, the method comprising:
providing a two-electrode configuration having a working electrode and a counter electrode; and
anodizing the working electrode in a polar organic electrolyte for providing fluoride ions, the polar organic electrolyte optimized to maintain dynamic equilibrium between growth and dissolution processes to promote growth of the nanotube array by providing sustained chemical oxidation of the working electrode and pore growth by dissolution of formed oxides.

2. The method of claim 1 wherein the polar organic electrolyte is ethylene glycol or a polar organic electrolyte consisting of a formamide, a dimethyl sulfoxide, a dimethylformamide or a N-methylformamide for providing fluoride ions.

3. The method of claim 1 wherein the working electrode is a titanium foil having a thickness sufficient to provide synthesis of self-aligned closely packed nanotube arrays of in excess of 10 μm in length.

4. The method of claim 1 wherein the working electrode is a titanium foil having a thickness sufficient to provide synthesis of self-aligned closely packed nanotube arrays of at least 134 μm in length.

5. The method of claim 1 wherein the working electrode is a titanium foil having a thickness sufficient to provide synthesis of self-aligned closely packed nanotube arrays in excess of 1000 μm in length.

6. The method of claim 5 wherein the thickness of the titanium foil being at least 2.0 mm.

7. The method of claim 3 wherein the thickness of the titanium foil being between 0.25 mm and 2.0 mm.

8. The method of claim 1 wherein the polar organic electrolyte is an aqueous electrolyte, an amide based electrolyte, or a non-aqueous electrolyte.

9. The method of claim 1 wherein the polar organic electrolyte is an ethylene glycol containing 0.3 wt % NH₄F and 2% H₂O.

10. The method of claim 1 wherein the polar organic electrolyte is a fluoride containing organic electrolyte of DMSO containing hydrofluoric acid, potassium fluoride, or ammonium fluoride.

11. The method of claim 10 further comprising the step of optimizing the electrolytic composition of the fluoride containing organic electrolyte and duration of oxidation to provide complete anodization of the working electrode and control of the length of the nanotube array.

12. The method of claim 1 further comprising the step of assisting in increasing length of the nanotube array by anodizing the working electrode in the polar organic electrolyte having 0.5 wt % NH₄F and 3.0% H₂O in ethylene glycol.

13. The method of claim 1 wherein the counter electrode comprises a platinum foil.

14. A method for forming a vertically oriented nanotube array using electrochemical oxidation, the method comprising:
providing a two-electrode configuration having a working electrode and a counter electrode;
anodizing the working electrode in an electrolyte having fluoride ions to assist in providing a formed oxide;
dissolving the formed oxide to form the nanotube array;
maintaining dynamic equilibrium between growth and dissolution processes by controlling one or more anodization variables; and
growing the nanotube array to a total length to form to the nanotube array by sustained oxidation of the working electrode.

15. The method of claim 14 wherein the electrolyte is a polar organic electrolyte to provide the fluoride ions, the polar organic electrolyte from a set consisting of:
a) formamide (FA);
b) dimethyl sulfoxide (DMSO);
c) dimethylformamide (DMF); and
d) N-methylformamide (NMF).

16. The method of claim 14 wherein the electrolyte is a polar organic electrolyte comprising ammonium fluoride (NH₄F).

17. The method of claim 14 wherein the working electrode comprises a titanium foil.

18. The method of claim 17 wherein the counter electrode comprises a platinum foil.

19. The method of claim 18 wherein the formed oxide comprises a titanium oxide.

20. The method of claim 19 wherein the electrolyte comprises a solution of ethylene glycol, wherein the ethylene glycol assists in minimizing lateral etching of the nanotubes.

21. The method of claim 20 further comprising completely anodizing a thickness of the titanium foil by optimizing the electrolyte comprising a weight % of NH₄F and H₂O in the solution of ethylene glycol.

22. The method of claim 21 wherein the anodization variables include at least:
a) an anodization voltage;
b) an anodization time;
c) a wt % of H₂O in the solution of ethylene glycol; and
d) a wt % of NH₄F.

23. The method of claim 22 further comprising the step of obtaining at least the total length of 1000 μm for the nanotube array using titanium foil of sufficient thickness and anodizing the titanium foil in the electrolyte having the wt % NH₄F and H₂O in the solution of ethylene glycol at sufficient anodization voltage and the time.

24. A method for forming a nanotube array using electro-chemical oxidation, the method comprising:
providing a two-electrode configuration having a titanium foil as a working electrode and a platinum foil as a counter electrode;
anodizing the titanium foil in a polar organic electrolyte solution to form a titanium dioxide;
dissolving the titanium dioxide to form the nanotube array of long range order exhibiting close-packing and high aspect ratios;
growing the nanotube array to an optimal length given the working electrode thickness by sustained oxidation of the titanium foil and pore growth; and
maintaining dynamic equilibrium between growth and dissolution processes.

25. The method of claim 24 further comprising the step of providing the nanotube array of at least 1000 μm in length from 0.5 mm thick titanium foil by anodizing the foil in the polar organic electrolyte having a wt % NH₄F and wt % H₂O in a solution of ethylene glycol.

26. A nanotube array, comprising:
a plurality of self-aligned vertically oriented titania nanotubes;
wherein the plurality of self-aligned vertically oriented titania nanotubes being formed by electrochemical oxidation using a polar organic electrolyte.

27. A solar cell, comprising;
a solar cell surface;
a nanotube array attached to the surface, the nanotube array comprising a plurality of self-aligned vertically oriented titania nanotubes;
wherein the titania nanotube array being formed by electrochemical oxidation using a polar organic electrolyte.

28. A biofilter, comprising:
a biofilter surface;
a nanotube array attached to the surface, the nanotube array comprising a plurality of self-aligned vertically oriented titania nanotubes;
wherein the titania nanotube array being formed by electrochemical oxidation using a polar organic electrolyte.
